(19) United States
(12) Patent Application Publication
(10) Pub. No.: US 2017/0184675 A1
(43) Pub. Date: Jun. 29, 2017

(54) PROGNOSTIC AND HEALTH MONITORING SYSTEMS FOR CIRCUIT BREAKERS

(71) Applicant: Cooper Technologies Company, Houston, TX (US)

(72) Inventors: Benjamin Avery Freer, Syracuse, NY (US); Stephan P Iannce, Clay, NY (US); Joseph Michael Manahan, Manlius, NY (US)

(73) Assignee: Cooper Technologies Company, Houston, TX (US)

(21) Appl. No.: 15/374,216

(22) Filed: Dec. 9, 2016

Related U.S. Application Data
(60) Provisional application No. 62/271,777, filed on Dec. 28, 2015.

(51) Int. Cl. G01R 31/327

(52) U.S. Cl. CPC G01R 31/3277

(57) ABSTRACT

A system can include at least one circuit breaker. The system can also include a prognostic and health monitoring (PHM) system. The PHM system can include at least one measuring device that measures at least one parameter associated with the at least one circuit breaker. The PHM system can also include a controller that receives measurements made by the at least one measuring device and analyzes the measurements to evaluate a performance of the at least one circuit breaker. The measurements can be made while the at least one circuit breaker is in service.

### CROSS-REFERENCE TO RELATED APPLICATIONS

This application claims priority under 35 U.S.C. §119 to U.S. Provisional Patent Application Ser. No. 62/271,777, titled “Prognostic and Health Monitoring Systems For Circuit Breakers” and filed on Dec. 28, 2015, the entire contents of which are hereby incorporated herein by reference.

### TECHNICAL FIELD

The present disclosure relates generally to circuit breakers, and more particularly to systems, methods, and devices for prognostic and health monitoring systems for circuit breakers.

### BACKGROUND

Circuit breakers are devices that are used to open an electrical path, preventing power from flowing to downstream electrical devices. Essentially, a circuit breaker is a switch. While a circuit breaker can be opened and closed manually by a user, the principal function of a circuit breaker is to open during adverse electrical conditions (e.g., overload, short circuit). When a circuit breaker fails to operate during such an adverse electrical condition, there can be catastrophic results.

### SUMMARY

In general, in one aspect, the disclosure relates to a system. The system can include at least one circuit breaker. The system can also include a prognostic and health monitoring (PHM) system. The PHM system can include at least one measuring device that measures at least one parameter associated with the at least one circuit breaker. The PHM system can also include a controller that receives measurements made by the at least one measuring device and analyzes the measurements to evaluate a performance of the at least one circuit breaker. The measurements can be made while the at least one circuit breaker is in service.

In another aspect, the disclosure can generally relate to a prognostic and health monitoring (PHM) system. The PHM system can include at least one measuring device that is configured to measure at least one parameter associated with at least one circuit breaker. The PHM system can also include a controller configured to receive measurements made by the at least one measuring device and analyze the measurements to evaluate a performance of the at least one circuit breaker. The measurements can be made while the at least one circuit breaker is in service.

In yet another aspect, the disclosure can generally relate to a controller for evaluating a performance of at least one circuit breaker. The controller can include a memory comprising a number of instructions, and a hardware processor that executes the instructions. The controller can also include a control engine that follows the instructions by receiving a measurement from at least one measuring device, where the measurement is associated with at least one circuit breaker, analyzing the measurement in the context of at least one algorithm, and determining, based on analyzing the measurement, a performance of the at least one circuit breaker. The measurement can be made while the at least one circuit breaker is in service.

These and other aspects, objects, features, and embodiments will be apparent from the following description and the appended claims.

### BRIEF DESCRIPTION OF THE DRAWINGS

The drawings illustrate only example embodiments and are therefore not to be considered limiting in scope, as the example embodiments may admit to other equally effective embodiments. The elements and features shown in the drawings are not necessarily to scale, emphasis instead being placed upon clearly illustrating the principles of the example embodiments. Additionally, certain dimensions or positionings may be exaggerated to help visually convey such principles. In the drawings, reference numerals designate like or corresponding, but not necessarily identical, elements.

FIG. 1 shows an enclosure in which circuit breakers are disposed.

FIGS. 2 and 3 show circuit breakers that have deteriorated and are at risk of failing to function.

FIG. 4 shows a system diagram of a prognostic and health monitoring system for circuit breakers in accordance with certain example embodiments.

FIG. 5 shows a computing device in accordance with certain example embodiments.

FIG. 6 shows a temperature measuring device and a corresponding output used with example embodiments.

FIGS. 7 and 8 show graphs based on algorithms for monitoring the health of a circuit breaker in accordance with certain example embodiments.

FIG. 9 shows a system for monitoring circuit breakers in accordance with certain example embodiments.

### DETAILED DESCRIPTION

In general, example embodiments provide systems, methods, and devices for prognostic and health monitoring systems for circuit breakers. Example prognostic and health monitoring systems for circuit breakers provide a number of benefits. Such benefits can include, but are not limited to, preventing abrupt failure of circuit breakers in critical applications, longer useful life of circuit breakers, enable preventative maintenance practices, improved root cause diagnostics of circuit breaker failures, reduced operating costs, and compliance with industry standards that apply to circuit breakers located in certain environments.

For example, embodiments can generate estimates of the remaining useful life of a circuit breaker or components thereof based on actual (e.g., historical, real-time) data for a particular circuit breaker, for a particular style of circuit breaker, for a particular environment in which circuit breakers are located, for a particular brand of circuit breaker, and/or for any other categorization of circuit breaker. Example embodiments can predict the failure of a circuit breaker (or components thereof) to improve the safety of industrial environments in which the circuit breaker is disposed. Example embodiments can also help ensure efficient allocation of maintenance resources within a facility. Example embodiments can further provide a user with options to prolong the useful life of a circuit breaker or components thereof. Enclosures with which example embodiments are used can be for residential, commercial, and/or industrial applications.

In some cases, the example embodiments discussed herein can be used in any type of non-hazardous environments. Alternatively, example embodiments can be used in any hazardous environment, including but not limited to an airplane hangar, a drilling rig (as for oil, gas, or water), a production rig (as for oil or gas), a refinery, a chemical plant, a power plant, a mining operation, a wastewater treatment facility, and a steel mill. Circuit breakers described herein can be designed for any type of voltage (e.g., alternating current, direct current). In addition, the circuit breakers described herein can be designed for any level of voltage (e.g., 120V, 480V, 4 kV) and have any number of poles (e.g., one, three). A user may be any person that interacts with circuit breakers. Examples of a user may include, but are not limited to, an engineer, an electrician, an instrumentation and controls technician, a mechanic, an operator, a consultant, an inventory management system, an inventory manager, a regulatory entity, a foreman, a labor scheduling system, a contractor, and a manufacturer's representative.

The circuit breakers and example prognostic and health monitoring systems (or components thereof, including controllers) described herein can be made of one or more of a number of suitable materials to allow the circuit breaker and/or other associated components (e.g., an enclosure in which a circuit breaker is disposed) of a system to meet certain standards and/or regulations while also maintaining durability in light of the one or more conditions under which the circuit breakers and/or other associated components of the system can be exposed. Examples of such materials can include, but are not limited to, aluminum, stainless steel, fiberglass, glass, plastic, ceramic, and rubber.

Example circuit breakers (or portions thereof) and example prognostic and health monitoring systems described herein can be made from a single piece (as from a mold, injection mold, die cast, or extrusion process). In addition, or in the alternative, example circuit breakers (or portions thereof) and example prognostic and health monitoring systems can be made from multiple pieces that are mechanically coupled to each other. In such a case, the multiple pieces can be mechanically coupled to each other using one or more of a number of coupling methods, including but not limited to epoxy, welding, fastening devices, compression fittings, mating threads, and slotted fittings. One or more pieces that are mechanically coupled to each other can be coupled to each other in one or more of a number of ways, including but not limited to fixedly, hingedly, removeably, slidably, and threadably.

In the foregoing figures showing example embodiments of prognostic and health monitoring systems for circuit breakers, one or more of the components shown may be omitted, repeated, and/or substituted. Accordingly, example embodiments of prognostic and health monitoring systems for circuit breakers should not be considered limited to the specific arrangements of components shown in any of the figures. For example, features shown in one or more figures or described with respect to one embodiment can be applied to another embodiment associated with a different figure or description.

Further, if a component of a figure is described but not expressly shown or labeled in that figure, the label used for a corresponding component in another figure can be inferred to that component. Conversely, if a component in a figure is labeled but not described, the description for such component can be substantially the same as the description for the corresponding component in another figure. The numbering scheme for the various components in the figures herein is such that each component is a three digit number and corresponding components in other figures have the identical last two digits.

In addition, a statement that a particular embodiment (e.g., as shown in a figure herein) does not have a particular feature or component does not mean, unless expressly stated, that such embodiment is not capable of having such feature or component. For example, for purposes of present or future claims herein, a feature or component that is described as not being included in an example embodiment shown in one or more particular drawings is capable of being included in one or more claims that correspond to such one or more particular drawings herein.

While example embodiments described herein are directed to circuit breakers, prognostic and health monitoring systems can also be applied to any devices and/or components, regardless of whether such devices and/or components are disposed within an enclosure. As defined herein, an enclosure (also sometimes called an electrical enclosure) is any type of cabinet or housing inside of which is disposed electrical, mechanical, electro-mechanical, and/or electronic equipment. Such equipment can include, but is not limited to, a circuit breaker, a controller (also called a control module), a hardware processor, a power supply (e.g., a battery, a driver, a ballast), a sensor module, a safety barrier, a sensor, sensor circuitry, a light source, electrical cables, and electrical conductors. Examples of an electrical enclosure can include, but are not limited to, a breaker panel, a motor control center, a junction box, a motor control center, an electrical housing, a control panel, an indicating panel, and a control cabinet.

In certain example embodiments, circuit breakers and/or enclosures in which circuit breakers are disposed for which example prognostic and health monitoring systems are used are subject to meeting certain standards and/or requirements. For example, the National Electric Code (NEC), the National Electrical Manufacturers Association (NEMA), the International Electrotechnical Commission (IEC), the Federal Communication Commission (FCC), and the Institute of Electrical and Electronics Engineers (IEEE) set standards as to electrical enclosures, wiring, and electrical connections. Use of example embodiments described herein meet (and/or allow a corresponding device to meet) such standards when required. In some (e.g., PV solar) applications, additional standards particular to that application may be met by the electrical enclosures described herein.

As a specific example, the NEC requires that the cause of a circuit interruption be diagnosed prior to resetting a circuit breaker. Example embodiments automate the fault detection process. As a result, example embodiments can expedite the process of putting equipment into service while maintaining compliance with the NEC requirements.

If a component of a figure is described but not expressly shown or labeled in that figure, the label used for a corresponding component in another figure can be inferred to that component. Conversely, if a component in a figure is labeled but not described, the description for such component can be substantially the same as the description for the corresponding component in another figure. If a component of a figure is described but not expressly shown or labeled in that figure, the label used for a corresponding component in another figure can be inferred to that component. Conversely, if a component in a figure is labeled but not described, the description for such component can be substantially the same as the description for the corresponding component in another figure. The numbering scheme for the various components in the figures herein is such that each component is a three digit number and corresponding components in other figures have the identical last two digits.

Example embodiments of prognostic and health monitoring systems for circuit breakers will be described more fully hereinafter with reference to the accompanying drawings, in which example embodiments of prognostic and health monitoring systems for circuit breakers are shown. Prognostic and health monitoring systems for circuit breakers may, however, be embodied in many different forms and should not be construed as limited to the example embodiments set forth herein. Rather, these example embodiments are provided so that this disclosure will be thorough and complete, and will fully convey the scope of prognostic and health monitoring systems for circuit breakers to those of ordinary skill in the art. Like, but not necessarily the same, elements (also sometimes called components) in the various figures are denoted by like reference numerals for consistency.

Terms such as “first”, “second”, and “within” are used merely to distinguish one component (or part of a component or state of a component) from another. Such terms are not meant to denote a preference or a particular orientation, and are not meant to limit embodiments of prognostic and health monitoring systems for circuit breakers. In the following detailed description of the example embodiments, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

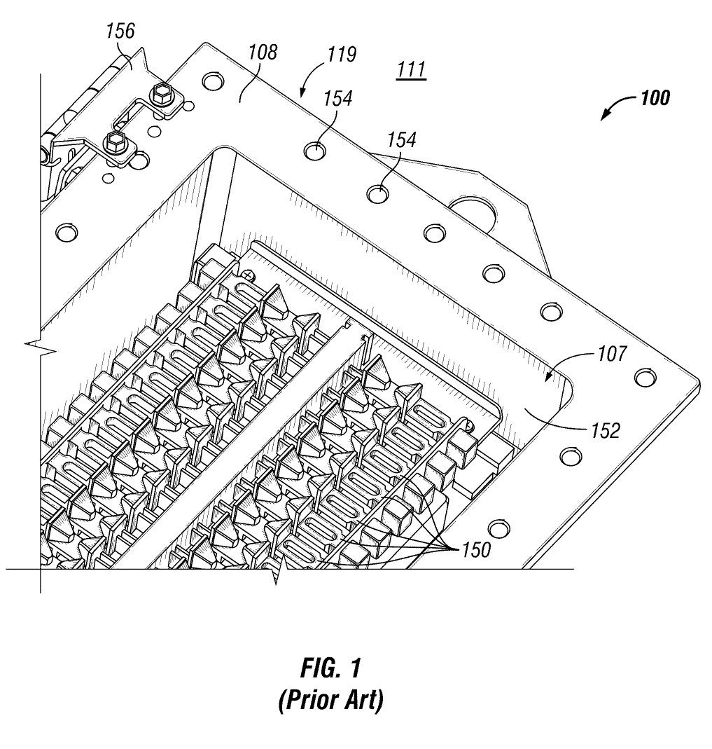

FIG. 1 shows system 100 that includes an enclosure 119 in which circuit breakers 150 are disposed. The enclosure 119 of FIG. 1 is in an open position (i.e., the enclosure cover (not shown) is separated from the enclosure body 152). The enclosure 119 is located in an ambient environment 111 (e.g., outdoors, a hazardous environment). The enclosure cover can be secured to the enclosure body 152 by a number of fastening devices (not shown) disposed within a number of apertures 154 around the perimeter of an enclosure engagement surface (not shown) (also called a flange) of the enclosure cover and around the perimeter of the enclosure engagement surface 108 (also called a flange 108) of the enclosure body 152. As discussed above, even though an explosion-proof enclosure is described in this particular example, example embodiments can be used with any type of enclosure placed in any type of environment.

When the enclosure cover and the enclosure body 152 are in the closed position relative to each other, the enclosure engagement surface 108 of the enclosure body 152 abuts against the enclosure engagement surface of the enclosure cover. When the enclosure 119 is an explosion-proof enclosure, as in this case, a flame path is formed between the enclosure engagement surface 108 of the enclosure body 152 and the enclosure engagement surface of the enclosure cover. The enclosure body forms a cavity 107 inside of which one or more components (e.g., circuit breakers 150, electrical cables) are disposed. When the enclosure cover and the enclosure body 152 are in the closed position relative to each other, then the cavity 107 is substantially enclosed.

A fastening device may be one or more of a number of fastening devices, including but not limited to a bolt (which may be coupled with a nut), a screw (which may be coupled with a nut), and a clamp. In addition, one or more optional hinges 156 can be secured to one side of the enclosure cover and a corresponding side of the enclosure body 152 so that, when all of the fastening devices are removed, as shown in FIG. 1, the enclosure cover may swing outward (i.e., an open position) from the enclosure body 152 using the one or more hinges 156. In one or more example embodiments, there are no hinges, and the enclosure cover can be completely separated from the enclosure body 152 when all of the fastening devices are removed.

The enclosure cover and the enclosure body 152 may be made of any suitable material, including metal (e.g., alloy, stainless steel), plastic, some other material, or any combination thereof. The enclosure cover and the enclosure body 152 may be made of the same material or different materials. In one or more example embodiments, on the end of the enclosure body 152 opposite the enclosure cover, one or more mounting brackets (hidden from view) are affixed to the exterior of the enclosure body 152 to facilitate mounting the enclosure 119. Using the mounting brackets, the enclosure 119 may be mounted to one or more of a number of surfaces and/or elements, including but not limited to a wall, a control cabinet, a cement block, an I-beam, and a U-bracket.

As stated above, if the enclosure 119 is an explosion-proof enclosure, certain applicable industry standards must be met. For example, in order to maintain a suitable flame path between the flange of the enclosure cover and the flange 108 of the enclosure body 152, all of the fastening devices must be properly engineered, machined, applied, and tightened within all of the apertures 154.

Because some enclosures, such as the enclosure 119 of FIG. 1, have so many fastening devices (e.g., more than 30), it can be extremely time-consuming to remove all of the fastening devices to open the enclosure 119, access the cavity 107, perform a visual inspection of each circuit breaker 150, and subsequently properly re-couple all of the fastening devices to return the enclosure 119 to a closed state. Also, if a circuit breaker 150 has ground fault circuit interrupter (GFCI) capability, the circuit breaker 150 must be tested periodically to ensure that it is operating properly. If these tests are not performed on these circuit breaker 150 with GFCI capability within a prescribed period of time relative to the most recent test, applicable standards (e.g., NEC) and/or regulations are violated. The standards and/or regulations for such devices are designed to promote safety, and so a violation of these standards and/or regulations can result in significant damage.

Further, regardless of whether the circuit breaker 150 has GFCI capability, and regardless of the type of enclosure, if any, that the circuit breaker 150 is disposed, testing the circuit breaker 150 to ensure proper functionality is disruptive and time-consuming. Currently, circuit breakers 150 are tested by shutting off the power that flows through the circuit breaker 150 and isolating (e.g., removing) the circuit breaker 150 so that the resistance between contacts in the circuit breaker 150 can be measured. This can result in significant down of equipment having circuits in which the circuit breakers 150 are used.

Moreover, the resistance readings taken for a circuit breaker 150 do not provide an indication to a user of whether the circuit breaker 150 is failing and, if so, to what extent that failure has progressed. The user likely does not have access to historical resistance reading for that circuit breaker 150. Further, the user does not have access to other critical information, including but not limited to the amount of current flowing through the circuit breaker 150 over time, the temperatures that the circuit breaker 150 is exposed to over time, the relative humidity that the circuit breaker 150 is exposed to over time, and the number of operations of the circuit breaker 150.

Further, if a circuit breaker 150 trips (as from a ground fault), a user (e.g., an electrician) must determine the source of the fault before the circuit breaker 150 can be re-closed. This means that the user must test not only the circuit breaker 150, but also any of the devices downstream of (receiving power through) the circuit breaker 150. For purposes herein, a circuit breaker 150 can also include any devices coupled to and receiving power through the circuit breaker 150.

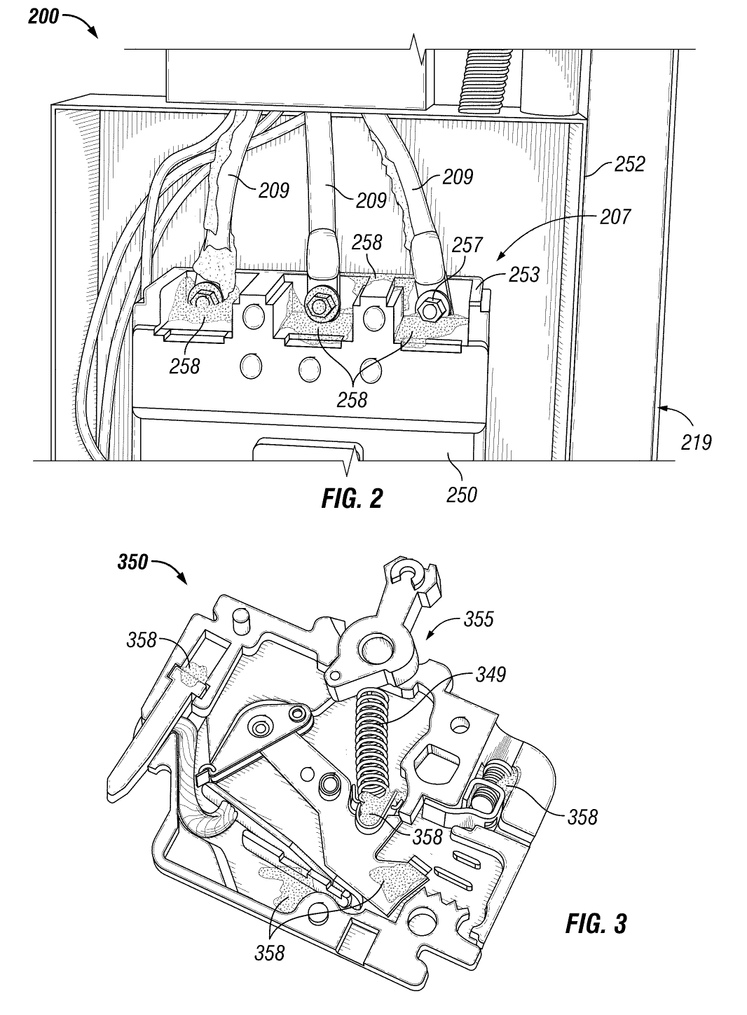

FIGS. 2 and 3 show circuit breakers that have deteriorated and at risk of failing to function. Specifically, FIG. 2 shows a front view of a system 200 that includes an open enclosure 219 in which a circuit breaker 250 is disposed. FIG. 3 shows a side view of a partially disassembled circuit breaker 350. The enclosure 219 of FIG. 2 can be substantially similar to the enclosure 119 of FIG. 1, except as described below. Further, the circuit breaker 250 of FIG. 2 and the circuit breaker 350 of FIG. 3 can be substantially similar to the circuit breaker 150 of FIG. 1, except as described below.

Circuit breakers can deteriorate and fail for any of a number of reasons. Such reasons can include, but are not limited to, corrosion, excessive temperatures, excessive operations, mechanical wear, excessive current, electrical failure (e.g., short to ground), and mechanical failure. Referring to FIGS. 1-3, a few of these reasons are shown in FIGS. 2 and 3. In FIG. 2, the circuit breaker 250 is disposed within the cavity 207 formed by the enclosure body 252 and has three line-side terminals 253 along its top end. Each of the line-side terminals 253 is electrically coupled to an electrical conductor 209 using a coupling feature 257 (in this case, a nut and bolt).

If the enclosure 219 is located in an area with high humidity, is exposed to water, and/or is located in an environment with caustic chemicals, corrosion 258 can result. In this case, the corrosion 258 is disposed heavily on each of the line-side terminals 253, the coupling features 257, and the enclosure body 252. While not shown, there is also likely corrosion 258 inside the circuit breaker 250. The corrosion 258 eats away at the electrically-conductive material of the line-side terminals 253, the coupling features 257, and/or the electrical conductors 209. This reduces the effective cross-sectional area of each of these components, which causes wasted heat energy because the same amount of electrical current is flowing through the reduced electrically-conductive cross-sectional area.

As the corrosion 258 gets worse, the wasted heat energy increases, which increases the likelihood that the circuit breaker 250 and/or other components adjacent to the circuit breaker 250 will fail. If the corrosion 258 because so severe that it creates an open circuit, a fault can occur, which can cause a fire, sparking, and/or other conditions that can damage components disposed within the cavity 207 of the enclosure 219 and/or components electrically located downstream of the circuit breaker 250.

The circuit breaker 350 of FIG. 3 shows some of the internal components of the circuit breaker 350. There is corrosion 358 at multiple internal locations throughout the circuit breaker 350. Here, the corrosion 358 can affect the performance of the “switch” 355 (also called the trip mechanism 355) within the circuit breaker 350. Here, if the corrosion 358 is severe enough, the trip mechanism 355 will fail to open the circuit when it is supposed to do so. For example, the spring 349 of the trip mechanism 355 can break, preventing the trip mechanism 355 from operating.

Example embodiments can be used to actively and autonomously monitor and evaluate one or more circuit breakers in a system. Examples of some of the tasks that can be performed by example embodiments can include, but are not limited to, measure conditions (e.g., temperature, electrical parameters) associated with a circuit breaker, store the measurements, apply the measurements over time to algorithms, compare the results of the algorithms for one circuit breaker to the results of algorithms run for other circuit breakers that have one or more features (e.g., manufacturer, environmental conditions, current/voltage levels) that correspond to the circuit breaker, identify problems (e.g., mechanical failure of a component of the circuit breaker, electrical failure of a portion (e.g., load-side terminals) of the circuit breaker) arising with the circuit breaker, forecast when potential problems will materialize into actual problems, notify a user of the problems (in some cases, with specific details) with the circuit breaker, schedule maintenance for the circuit breaker, order replacement components and/or a replacement circuit breaker, and generate and submit reports to applicable regulatory entities. Therefore, the likelihood of unexpected adverse conditions arising because of a failure of a circuit breaker are substantially reduced using example embodiments.

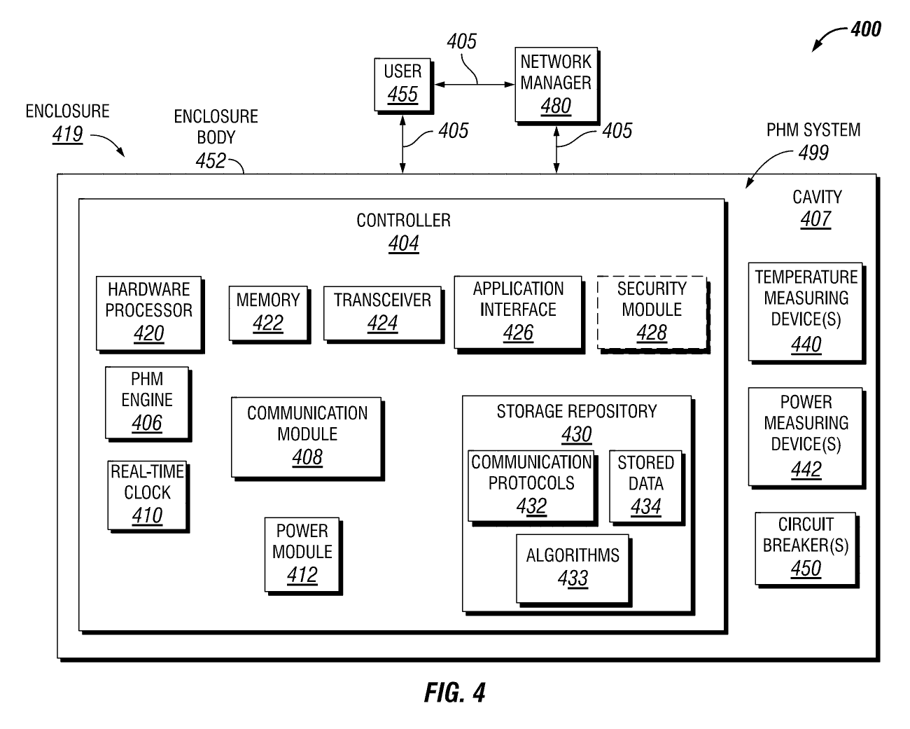

FIG. 4 shows a system diagram of a system 400 that includes a prognostic and health monitoring (“PHM”) system 499 of an enclosure 419 in accordance with certain example embodiments. The system 400 can include a user 455, a network manager 480, and at least one enclosure (e.g., enclosure 419). In addition to the PHM system 499, the enclosure 419 can include one or more circuit breakers 450.

The PHM system 499 can include one or more of a number of components. Such components, can include, but are not limited to, a controller 404, one or more temperature measuring devices 440, and one or more power measuring devices 442. The controller 404 of the PHM system 499 can also include one or more of a number of components. Such components, can include, but are not limited to, a PHM engine 406, a communication module 408, a real-time clock 410, a power module 412, a storage repository 430, a hardware processor 420, a memory 422, a transceiver 424, an application interface 426, and, optionally, a security module 428. The components shown in FIG. 4 are not exhaustive, and in some embodiments, one or more of the components shown in FIG. 4 may not be included in an example enclosure or other area in which one or more circuit breakers 450 can be disposed. Any component of the example system 400 can be discrete or combined with one or more other components of the system 400.

Referring to FIGS. 1-4, the user 455 is the same as a user defined above. The user 455 can use a user system (not shown), which may include a display (e.g., a GUI). The user 455 interacts with (e.g., sends data to, receives data from) the controller 404 of the PHM system 499 via the application interface 426 (described below). The user 455 can also interact with a network manager 480. Interaction between the user 455 and the PHM system 499 and/or the network manager 480 using communication links 405.

Each communication link 405 can include wired (e.g., Class 1 electrical cables, Class 2 electrical cables, electrical connectors, power line carrier, RS485) and/or wireless (e.g., Wi-Fi, visible light communication, cellular networking, Bluetooth, WirelessHART, ISA100) technology. For example, a communication link 405 can be (or include) one or more electrical conductors (e.g., electrical conductor 209) that are coupled to one or more components within the cavity 407 of the enclosure body 452 of the enclosure 419. A communication link 405 can transmit signals (e.g., power signals, communication signals, control signals, data) between the PHM system 499 and the user 455 and/or the network manager 480. One or more communication links 405 can also be used to transmit signals between components of the PHM system 499.

The network manager 480 is a device or component that controls all or a portion of a communication network that includes the controller 404 of the PHM system 499, additional enclosures, and the user 455 that are communicably coupled to the controller 404. The network manager 480 can be substantially similar to the controller 404. Alternatively, the network manager 480 can include one or more of a number of features in addition to, or altered from, the features of the controller 404 described below. As described herein, communication with the network manager 480 can include communicating with one or more other components (e.g., another enclosure) of the system 400. In such a case, the network manager 480 can facilitate such communication.

The one or more temperature measuring devices 440 and the one or more power measuring devices 442 can be any type of sensing device that measure one or more parameters within the enclosure 419. Examples of temperature measuring devices 440 can include, but are not limited to, a resistance temperature detector, a thermostat, a thermocouple, a thermistor, a passive infrared sensor, and an active infrared sensor. A temperature measuring device can measure one or more parameters related to temperature. Such parameters can include, but are not limited to, relative humidity, barometric pressure, and temperature. Such parameters can be measured at, or in close proximity to, at least a portion of a circuit breaker 450. Further, such parameters can be measured by the temperature measuring devices 440 and the one or more power measuring devices 442 while a circuit breaker 450 is in service.

Examples of a power measuring device 442 can include, but are not limited to, an ammeter, a voltmeter, a VAR meter, and an Ohmmeter. A power measuring device 442 can measure one or more parameters related to electric power. Such parameters can include, but are not limited to, a voltage, a current, a resistance, and a VAR. Such parameters can be measured at, or in close proximity to, at least a portion of a circuit breaker 450. A temperature measuring device 440 and a power measuring device 442 can include, in addition to the actual sensor, any ancillary components or devices used in conjunction with the sensor, including but not limited to a current transformer, a voltage transformer, a resistor, an integrated circuit, electrical conductors, electrical connectors, and a terminal block. Each of the temperature measuring devices 440 can measure a component of temperature continuously, periodically, based on the occurrence of an event, based on a command received from the PHM engine 406, and/or based on some other factor. Similarly, each of the power measuring devices 442 can measure a component of power continuously, periodically, based on the occurrence of an event, based on a command received from the PHM engine 406, and/or based on some other factor.

The user 455 and/or the network manager 480 can interact with the controller 404 of the PHM system 499 using the application interface 426 in accordance with one or more example embodiments. Specifically, the application interface 426 of the controller 404 receives data (e.g., information, communications, instructions, updates to firmware) from and sends data (e.g., information, communications, instructions) to the user 455 and/or the network manager 480. The user 455 and/or the network manager 480 can include an interface to receive data from and send data to the controller 404 in certain example embodiments. Examples of such an interface can include, but are not limited to, a graphical user interface, a touchscreen, an application programming interface, a keyboard, a monitor, a mouse, a web service, a data protocol adapter, some other hardware and/or software, or any suitable combination thereof.

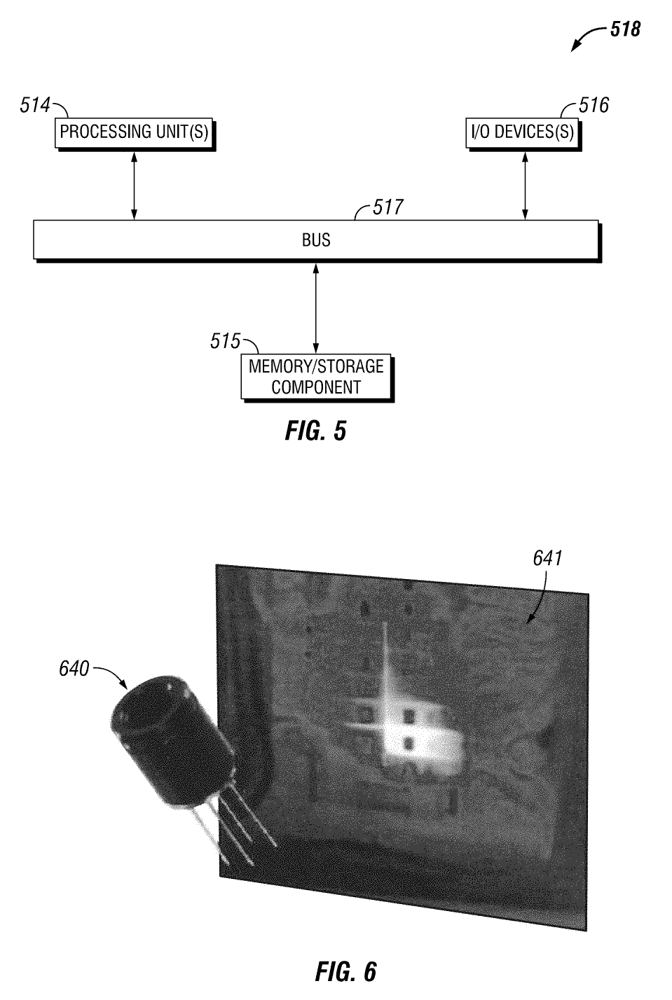

The controller 404, the user 455, and/or the network manager 480 can use their own system or share a system in certain example embodiments. Such a system can be, or contain a form of, an Internet-based or an intranet-based computer system that is capable of communicating with various software. A computer system includes any type of computing device and/or communication device, including but not limited to the controller 404. Examples of such a system can include, but are not limited to, a desktop computer with LAN, WAN, Internet or intranet access, a laptop computer with LAN, WAN, Internet or intranet access, a smart phone, a server, a server farm, an android device (or equivalent), a tablet, smartphones, and a personal digital assistant (PDA). Such a system can correspond to a computer system as described below with regard to FIG. 5.

Further, as discussed above, such a system can have corresponding software (e.g., user software, sensor software, controller software, network manager software). The software can execute on the same or a separate device (e.g., a server, mainframe, desktop personal computer (PC), laptop, PDA, television, cable box, satellite box, kiosk, telephone, mobile phone, or other computing devices) and can be coupled by the communication network (e.g., Internet, Intranet, Extranet, Local Area Network (LAN), Wide Area Network (WAN), or other network communication methods) and/or communication channels, with wire and/or wireless segments according to some example embodiments. The software of one system can be a part of, or operate separately but in conjunction with, the software of another system within the system 400.

The enclosure 419 can include an enclosure body 452. The enclosure body 452 can include at least one wall that forms a cavity 407. In some cases, the enclosure body 452 (which can include a corresponding enclosure cover) can be designed to comply with any applicable standards so that the enclosure 419 can be located in a particular environment (e.g., a hazardous environment). For example, if the enclosure 419 is located in an explosive environment, the enclosure body 452 can be explosion-proof. According to applicable industry standards, an explosion-proof enclosure is an enclosure that is configured to contain an explosion that originates inside, or can propagate through, the enclosure.

Continuing with this example, the explosion-proof enclosure is configured to allow gases from inside the enclosure to escape across joints of the enclosure and cool as the gases exit the explosion-proof enclosure. The joints are also known as flame paths and exist where two surfaces meet and provide a path, from inside the explosion-proof enclosure to outside the explosion-proof enclosure, along which one or more gases may travel. A joint may be a mating of any two or more surfaces. Each surface may be any type of surface, including but not limited to a flat surface, a threaded surface, and a serrated surface.

The enclosure body 452 of the enclosure 419 can be used to house one or more components of the PHM system 499, including one or more components of the controller 404. For example, as shown in FIG. 4, the controller 404 (which in this case includes the PHM engine 406, the communication module 408, the real-time clock 410, the power module 412, the storage repository 430, the hardware processor 420, the memory 422, the transceiver 424, the application interface 426, and the optional security module 428), the circuit breakers 450, the temperature measuring devices 440, and the power measuring devices 142 are disposed in the cavity 407 formed by the enclosure body 452. In alternative embodiments, any one or more of these or other components of the PHM system 499 can be disposed on the enclosure body 452 and/or remotely from the enclosure body 452.

The storage repository 430 can be a persistent storage device (or set of devices) that stores software and data used to assist the controller 404 in communicating with the user 455 and the network manager 480 within the system 400 (and, in some cases, with other systems). In one or more example embodiments, the storage repository 430 stores one or more communication protocols 432, algorithms 433, and stored data 434. The communication protocols 432 can be any of a number of protocols that are used to send and/or receive data between the controller 404 and the user 455 and the network manager 480. One or more of the communication protocols 432 can be a time-synchronized protocol. Examples of such time-synchronized protocols can include, but are not limited to, a highway addressable remote transducer (HART) protocol, a wirelessHART protocol, and an International Society of Automation (ISA) 100 protocol. In this way, one or more of the communication protocols 432 can provide a layer of security to the data transferred within the system 400.

The algorithms 433 can be any procedures (e.g., a series of method steps), formulas, logic steps, mathematical models, and/or other similar operational procedures that the PHM engine 406 of the controller 404 follows based on certain conditions at a point in time. An example of an algorithm 433 is measuring (using, for example, the power measuring devices 442 and the temperature measuring devices 440) various parameters associated with the circuit breakers 450, storing (using the stored data 434 in the storage repository 430), and/or evaluating the current and voltage delivered to and delivered by the temperature measuring devices 440 over time (as measured by the real-time clock 410).

Algorithms 433 can be focused on the circuit breakers 450. For example, there can be one or more algorithms 433 that focus on the expected useful life of a circuit breaker 450. Another example of an algorithm 433 is comparing and correlating data collected with a particular circuit breaker 450 with corresponding data from one or more other circuit breakers 450. Any algorithm 433 can be altered (for example, using machine-learning techniques such as alpha-beta) over time by the PHM engine 406 based on actual performance data so that the algorithm 433 can provide more accurate results over time. As another example, when one or more circuit breakers 450 of the enclosure 419 are determined to begin failing, the algorithm 433 can direct the PHM engine 406 to generate an alarm for predictive maintenance. If data from other circuit breakers is used in an algorithm to predict the performance of a particular circuit breaker, then the PHM engine 406 can determine which other circuit breakers (using, for example, particular data) are used.

As example, an algorithm 433 can be to continuously monitor the current (as measured by the power measuring devices 442 and stored as stored data 434) that flows through the line-side terminals (e.g., line-side terminals 253) and the load-side terminals of a circuit breaker 450. The algorithm can detect variations of the current flowing through the circuit breaker 450 and predict failure of the circuit breaker 450 (including a specific portion thereof).

Yet another example algorithm 433 can be to measure and analyze the magnitude and number of surges (ringing waves) that a circuit breaker 450 is subjected to over time. The algorithm 433 can predict the expected useful life of the circuit breaker 450 based on a threshold value. Still another example algorithm 433 can be to measure and analyze the efficiency of a circuit breaker 450 over time. An alarm can be generated by the PHM engine 406 when the efficiency of the circuit breaker 450 falls below a threshold value, indicating failure of the circuit breaker 450.

An algorithm 433 can use any of a number of mathematical formulas and/or algorithms. For example, an algorithm 433 can use linear or polynomial regression. In some cases, an algorithm 433 can be adjusted based on a parameter measured by a temperature measuring device 440 and/or a power measuring device 442. For example, an algorithm 433 that includes a polynomial regression can be adjusted based on ambient air temperature measured by a temperature measuring device 440. As described below, an algorithm 433 can be used in correlation analysis. In such a case, an algorithm can use any of a number of correlation and related (e.g., closeness-to-fit) models, including but not limited to Chi-squared and Kolmogorov-Smirnov.

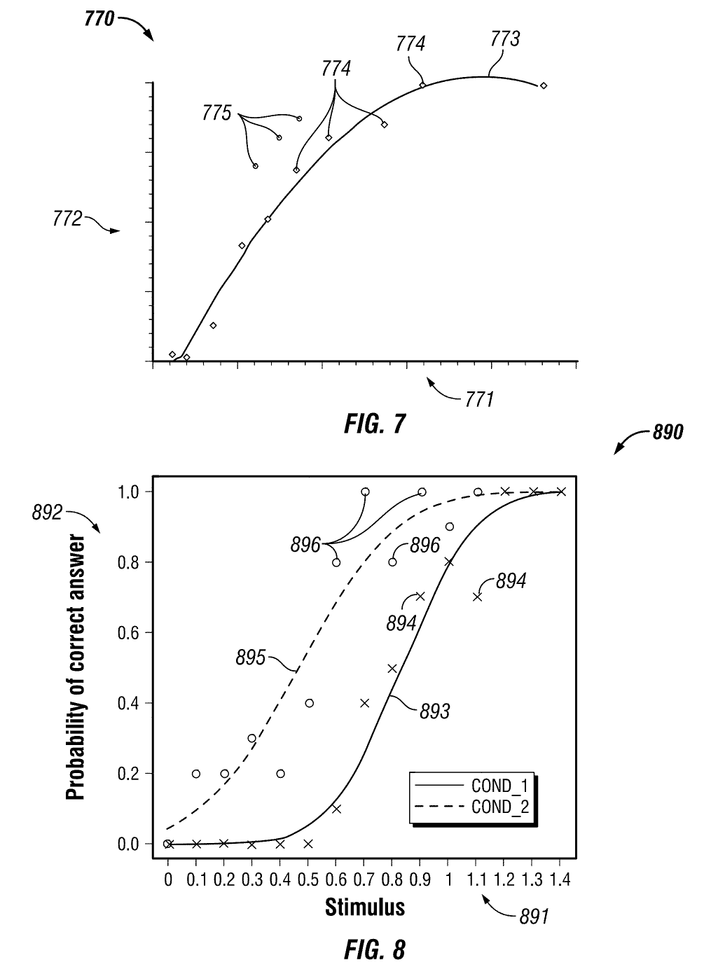

For example, an algorithm 433 can develop a stress versus life relationship using accelerated life testing for the circuit breaker 450 or a component thereof. One instance would be an actual lifetime temperature of the line-side terminals (e.g., line-side terminals 253) versus a modeled or estimated temperature profile of the line-side terminals, where the profile can be based, at least in part, on stored data 434 measured for other circuit breakers. As another example, an algorithm 433 can measure and analyze real-time application stress conditions of the circuit breaker 450 or components thereof over time and use developed models to estimate the life of the circuit breaker 450 or components thereof. In such a case, mathematical models can be developed using one or more mathematical theories (e.g., Arrhenius theory, Palmgran-Miner Rules) to predict useful life of the circuit breaker 450 or components thereof under real stress conditions. As yet another example, an algorithm 433 can use predicted values and actual data to estimate the remaining life of the circuit breaker 450 or components thereof. FIGS. 7 and 8 show examples of the use of algorithms 433 in determining the condition of a circuit breaker 450.

Stored data 434 can be any data associated with the circuit breaker 450 (including other circuit breakers and/or any components thereof), any measurements taken by the temperature measuring devices 440, measurements taken by the power measuring devices 442, threshold values, results of previously run or calculated algorithms, and/or any other suitable data. Such data can be any type of data, including but not limited to historical data for the circuit breaker 450, historical data for other circuit breakers, calculations, measurements taken by the temperature measuring device 440, and measurements taken by the power measuring devices 442. The stored data 434 can be associated with some measurement of time derived, for example, from the real-time clock 410.

Examples of a storage repository 430 can include, but are not limited to, a database (or a number of databases), a file system, a hard drive, flash memory, some other form of solid state data storage, or any suitable combination thereof. The storage repository 430 can be located on multiple physical machines, each storing all or a portion of the communication protocols 432, the algorithms 433, and/or the stored data 434 according to some example embodiments. Each storage unit or device can be physically located in the same or in a different geographic location.

The storage repository 430 can be operatively connected to the PHM engine 406. In one or more example embodiments, the PHM engine 406 includes functionality to communicate with the user 455 and the network manager 480 in the system 400. More specifically, the PHM engine 406 sends information to and/or receives information from the storage repository 430 in order to communicate with the user 455 and the network manager 480. As discussed below, the storage repository 430 can also be operatively connected to the communication module 408 in certain example embodiments.

In certain example embodiments, the PHM engine 406 of the controller 404 controls the operation of one or more components (e.g., the communication module 408, the real-time clock 410, the transceiver 424) of the controller 404. For example, the PHM engine 406 can activate the communication module 408 when the communication module 408 is in “sleep” mode and when the communication module 408 is needed to send data received from another component (e.g., the user 455, the network manager 480) in the system 400.

As another example, the PHM engine 406 can acquire the current time using the real-time clock 410. The real time clock 410 can enable the controller 404 to monitor the circuit breaker 450 even when the controller 404 has no communication with the network manager 480. As yet another example, the PHM engine 406 can direct the power measuring devices 442 to measure and send power consumption information of the circuit breaker 450 to the network manager 480.

The PHM engine 406 can be configured to perform a number of functions that help prognosticate and monitor the health of the circuit breaker 450 (or components thereof), either continually or on a periodic basis. For example, the PHM engine 406 can execute any of the algorithms 433 stored in the storage repository 430. As a specific example, the PHM engine 406 can measure (using the power measuring devices 442), store (as stored data 434 in the storage repository 430), and evaluate, using an algorithm 433, the current and voltage delivered to and delivered by the circuit breaker 450 over time.

As another specific example, the PHM engine 406 can use one or more algorithms 433 that focus on certain components of the circuit breaker 450. For example, the PHM engine 406 can use one or more algorithms 433 that focus on the integrity of the trip mechanism (e.g., trip mechanism 355) of the circuit breaker 450. The PHM engine 406 can also monitor moisture levels (as measured by the temperature measuring devices 440 and stored as stored data 434) within the enclosure body 452 (or, more specifically, at all or portions of the circuit breaker 450) over time and notify the user that there is a leak in the enclosure body 452 when moisture levels exceed a threshold value (as stored as stored data 434). The PHM engine 406 can also determine, using data collected by the power measurement devices 442, whether the high moisture levels have caused corrosion 358 in portions of the circuit breaker 450.

The PHM engine 406 can analyze and detect short-term problems that can arise with a circuit breaker 450. For example, the PHM engine 406 can compare new data (as measured by a temperature measuring device 440 and/or a power measuring device 442) to a reference curve (part of the stored data 434) for that particular circuit breaker 450 or for a number of circuit breakers 450 of the same type (e.g., manufacturer, model number, current rating). The PHM engine 406 can determine whether the current data fits the curve, and if not, the PHM engine 406 can determine how severe a problem with the circuit breaker might be based on the extent of the lack of fit.

The PHM engine 406 can also analyze and detect long-term problems that can arise with a circuit breaker 450. For example, the PHM engine 406 can compare new data (as measured by a temperature measuring device 440 and/or a power measuring device 442) to historical data (part of the stored data 434) for that particular circuit breaker 450 and/or for a number of circuit breakers 450 of the same type (e.g., manufacturer, model number, current rating). In such a case, the PHM engine 406 can make adjustments to one or more of the curves based, in part, on actual performance and/or data collected while testing one or more of the circuit breakers 450 while those circuit breakers 450 are out of service.

The PHM engine 406 can also collect data, using the network manager 480, of one or more circuit breakers outside the enclosure 419, store the data as stored data 434, and compare this data with corresponding data (as collected by the temperature measuring devices 440 and the power measuring devices 442 and stored as stored data 434) of the circuit breakers 450 within the enclosure 419 to see if a correlation can be developed.

Real-time stress information collected in the enclosure 419 by the temperature measuring devices 440 and the power measuring devices 442 can be used by the PHM engine 406, along with stress-life models stored in storage repository 430, to predict the useful life of the circuit breaker 450 and/or components thereof. As another example, the PHM engine 406 can determine whether one or more circuit breakers 450 within the enclosure 419 are failing and generate an alarm for predictive maintenance, schedule the required maintenance, reserve replacement parts in an inventory management system, order replacement parts, and/or perform any other functions that actively repair or replace the failing circuit breaker 450.

As another example, the PHM engine 406 can continuously monitor the current (as measured by the power measuring devices 442 and stored as stored data 434) output by the load-side terminals of the circuit breaker 450. By combining the current and temperature information, the PHM engine 406 can use one or more algorithms 433 to infer the resistance of the circuit breaker 450. One such algorithm 433 can be a model of a temperature versus current curve for the circuit breaker 450, as shown in FIGS. 7 and 8 below. The resulting temperature versus current curve can be based on a specification sheet for a circuit breaker. In addition, or in the alternative, the resulting temperature versus current curve can be generated and updated automatically based on the performance over time of a new circuit breaker.

As still another example, the PHM engine 406 can monitor a temperature (using the temperature measuring devices 440) of acritical component (e.g., the trip mechanism) of the circuit breaker 450 over time. The PHM engine 406 can estimate the remaining life of the component of the circuit breaker 450 based on degradation curves of those components and threshold values established for those components.

The PHM engine 406 can also measure and record the number of operations of the trip mechanism over time. A trip operation can be stored as stored data 434 in the storage repository 430. Each occurrence of a trip operation can be recorded as a voluntary event (e.g., the trip mechanism is operated by a user 455) or an involuntary event (e.g., the trip mechanism is operated because of a ground fault). The PHM engine 406 can further measure (using the power measuring devices 442) and analyze the magnitude and number of surges that the circuit breaker 450 is subjected to over time. Using an algorithm 433, the PHM engine 406 can predict, using stored data 443 for the circuit breaker 450 and other circuit breakers, the expected useful life of the circuit breaker 450 based on a threshold value.

The PHM engine 406 can provide control, communication, and/or other similar signals to the user 455, the network manager 480, the temperature measuring devices 440, and the power measuring devices 442. Similarly, the PHM engine 406 can receive control, communication, and/or other similar signals from the user 455, the network manager 480, the temperature measuring devices 440, and the power measuring devices 442. The PHM engine 406 can control each of the temperature measuring devices 440 and the power measuring devices 442 automatically (for example, based on one or more algorithms 433) and/or based on control, communication, and/or other similar signals received from another device through a communication link 405. As an example, when a temperature measuring device 440 is an infrared sensor, the PHM engine 406 can direct the infrared sensor to move so that multiple components (or portions thereof) can be measured by the infrared sensor.

As yet another example, the PHM engine 406 can also perform monitoring of devices downstream from one or more of the circuit breakers 450. As a result, the PHM engine 406 can perform fault prediction and root cause analysis, of a circuit breaker 450 and/or the devices receiving power through the circuit breaker 450, during an adverse condition (e.g., a ground fault). As stated above, the NEC requires a user 455 (e.g., an electrician) to know the source of a fault before resetting a circuit breaker 450 that has tripped. In this way, the PHM engine 406 enables a user 455 to know the source (e.g., a particular device) of a fault and thereby eliminate the need to open the enclosure 419 and perform a diagnosis within the enclosure 419. Instead, the user 455 can focus on the downstream devices, often located outside the enclosure 419, based on the information provided by the PHM engine 406. The PHM engine 406 may include a printed circuit board, upon which the hardware processor 420 and/or one or more discrete components of the controller 404 are positioned.

In certain embodiments, the PHM engine 406 of the controller 404 can communicate with one or more components of a system external to the system 400 in furtherance of prognostications and evaluations of the circuit breaker 450. For example, the PHM engine 406 can interact with an inventory management system by ordering a circuit breaker (or one or more components thereof) to replace the circuit breaker 450 (or one or more components thereof) that the PHM engine 406 has determined to fail or be failing. As another example, the PHM engine 406 can interact with a workforce scheduling system by scheduling a maintenance crew to repair or replace the circuit breaker 450 (or portion thereof) when the PHM engine 406 determines that the circuit breaker 450 or portion thereof requires maintenance or replacement. In this way, the controller 404 is capable of performing a number of functions beyond what could reasonably be considered a routine task.

In certain example embodiments, the PHM engine 406 can include an interface that enables the PHM engine 406 to communicate with one or more components (e.g., temperature measuring devices 440) of the circuit breaker 450. For example, if the temperature measuring devices 440 of the circuit breaker 450 operate under IEC Standard 62386, then the temperature measuring devices 440 can have a serial communication interface that will transfer data (e.g., stored data 434) measured by the temperature measurement devices 440. In such a case, the PHM engine 406 can also include a serial interface to enable communication with the temperature measuring devices 440. Such an interface can operate in conjunction with, or independently of, the communication protocols 432 used to communicate between the controller 404 and the user 455 and/or the network manager 480.

The PHM engine 406 (or other components of the controller 404) can also include one or more hardware components and/or software elements to perform its functions. Such components can include, but are not limited to, a universal asynchronous receiver/transmitter (UART), a serial peripheral interface (SPI), a direct-attached capacity (DAC) storage device, an analog-to-digital converter, an inter-integrated circuit (I²C), and a pulse width modulator (PWM).

The communication module 408 of the controller 404 determines and implements the communication protocol (e.g., from the communication protocols 432 of the storage repository 430) that is used when the PHM engine 406 communicates with (e.g., sends signals to, receives signals from) the user 455, the network manager 480, the temperature measuring devices 440, and/or the power measuring devices 442. In some cases, the communication module 408 accesses the stored data 434 to determine which communication protocol is used to communicate with the temperature measurement device 440 or the power measurement device 442 associated with the stored data 434. In addition, the communication module 408 can interpret the communication protocol 432 of a communication received by the controller 404 so that the PHM engine 406 can interpret the communication.

The communication module 408 can send and receive data between the network manager 480 and/or the users 450 and the controller 404. The communication module 408 can send and/or receive data in a given format that follows a particular communication protocol 432. The PHM engine 406 can interpret the data packet received from the communication module 408 using the communication protocol 432 information stored in the storage repository 430. The PHM engine 406 can also facilitate the data transfer between the temperature measurement devices 440 and the power measurement devices 442, and the network manager 480 or a user 455 by converting the data into a format understood by the communication module 408.

The communication module 408 can send data (e.g., communication protocols 432, algorithms 433, stored data 434, operational information, alarms) directly to and/or retrieve data directly from the storage repository 430. Alternatively, the PHM engine 406 can facilitate the transfer of data between the communication module 408 and the storage repository 430. The communication module 408 can also provide encryption to data that is sent by the controller 404 and decryption to data that is received by the controller 404. The communication module 408 can also provide one or more of a number of other services with respect to data sent from and received by the PHM system 404. Such services can include, but are not limited to, data packet routing information and procedures to follow in the event of data interruption.

The real-time clock 410 of the controller 404 can track clock time, intervals of time, an amount of time, and/or any other measure of time. The real-time clock 410 can also count the number of occurrences of an event, whether with or without respect to time. Alternatively, the PHM engine 406 can perform the counting function. The real-time clock 410 is able to track multiple time measurements concurrently. The real-time clock 410 can track time periods based on an instruction received from the PHM engine 406, based on an instruction received from the user 455, based on an instruction programmed in the software for the controller 404, based on some other condition or from some other component, or from any combination thereof.

The real-time clock 410 can be configured to track time when there is no power delivered to the controller 404 using, for example, a super capacitor or a battery backup. In such a case, when there is a resumption of power delivery to the controller 404, the real-time clock 410 can communicate any aspect of time to the controller 404. In such a case, the real-time clock 410 can include one or more of a number of components (e.g., a super capacitor, an integrated circuit) to perform these functions.

The power module 412 of the controller 404 provides power to one or more components (e.g., PHM engine 406, real-time clock 410, PHM engine 406) of the controller 404. The power module 412 can include one or more of a number of single or multiple discrete components (e.g., transistor, diode, resistor), and/or a microprocessor. The power module 412 may include a printed circuit board, upon which the microprocessor and/or one or more discrete components are positioned. In some cases, power measuring devices 442 can measure one or more elements of power that flows into, out of, and/or within the power module 412 of the controller 404. The power module 412 can receive power from a power source external to the system 400. Such external source of power can also be used to provide power to the circuit breakers 450.

The power module 412 can include one or more components (e.g., a transformer, a diode bridge, an inverter, a converter) that receives power (for example, through an electrical cable) from a source external to the enclosure 419 and generates power of a type (e.g., alternating current, direct current) and level (e.g., 12V, 24V, 420V) that can be used by the other components of the PHM system 499 and/or within the enclosure 419. The power module 412 can use a closed control loop to maintain a preconfigured voltage or current with a tight tolerance at the output. The power module 412 can also protect some or all of the rest of the electronics (e.g., hardware processor 420, transceiver 424) in the enclosure 419 from surges generated in the line.

In addition, or in the alternative, the power module 412 can be a source of power in itself to provide signals to the other components of the controller 404 and/or the temperature measuring devices 440. For example, the power module 412 can be a battery. As another example, the power module 412 can be a localized photovoltaic power system. The power module 412 can also have sufficient isolation in the associated components of the power module 412 (e.g., transformers, opto-couplers, current and voltage limiting devices) so that the power module 412 is certified to provide power to an intrinsically safe circuit.

In certain example embodiments, the power module 412 of the controller 404 can also provide power and/or control signals, directly or indirectly, to one or more of the temperature measuring devices 440 and/or one or more of the power measuring devices 442. In such a case, the PHM engine 406 can direct the power generated by the power module 412 to the power measuring devices 442 and/or the temperature measuring devices 440. In this way, power can be conserved by sending power to the power measuring devices 442 and/or the temperature measuring devices 440 when those devices need power, as determined by the PHM engine 406.

The hardware processor 420 of the controller 404 executes software, algorithms (e.g., algorithms 433), and firmware in accordance with one or more example embodiments. Specifically, the hardware processor 420 can execute software on the PHM engine 406 or any other portion of the controller 404, as well as software used by the user 455 and the network manager 480. The hardware processor 420 can be an integrated circuit, a central processing unit, a multi-core processing chip, SoC, a multi-chip module including multiple multi-core processing chips, or other hardware processor in one or more example embodiments. The hardware processor 420 can be known by other names, including but not limited to a computer processor, a microprocessor, and a multi-core processor.

In one or more example embodiments, the hardware processor 420 executes software instructions stored in memory 422. The memory 422 includes one or more cache memories, main memory, and/or any other suitable type of memory. The memory 422 can include volatile and/or non-volatile memory. The memory 422 is discretely located within the controller 404 relative to the hardware processor 420 according to some example embodiments. In certain configurations, the memory 422 can be integrated with the hardware processor 420.

In certain example embodiments, the controller 404 does not include a hardware processor 420. In such a case, the controller 404 can include, as an example, one or more field programmable gate arrays (FPGAs), one or more insulated-gate bipolar transistors (IGBTs), one or more integrated circuits (ICs). Using FPGAs, IGBTs, ICs, and/or other similar devices known in the art allows the controller 404 (or portions thereof) to be programmable and function according to certain logic rules and thresholds without the use of a hardware processor. Alternatively, FPGAs, IGBTs, ICs, and/or similar devices can be used in conjunction with one or more hardware processors 420.

The transceiver 424 of the controller 404 can send and/or receive control and/or communication signals. Specifically, the transceiver 424 can be used to transfer data between the controller 404 and the user 455 and the network manager 480. The transceiver 424 can use wired and/or wireless technology. The transceiver 424 can be configured in such a way that the control and/or communication signals sent and/or received by the transceiver 424 can be received and/or sent by another transceiver that is part of the user 455 and/or the network manager 480. The transceiver 424 can use any of a number of signal types, including but not limited to radio signals.

When the transceiver 424 uses wireless technology, any type of wireless technology can be used by the transceiver 424 in sending and receiving signals. Such wireless technology can include, but is not limited to, Wi-Fi, visible light communication, cellular networking, and Bluetooth. The transceiver 424 can use one or more of any number of suitable communication protocols (e.g., ISA100, HART) when sending and/or receiving signals. Such communication protocols can be stored in the communication protocols 432 of the storage repository 430. Further, any transceiver information for the user 455 and/or the network manager 480 can be part of the stored data 434 (or similar areas) of the storage repository 430.

Optionally, in one or more example embodiments, the security module 428 secures interactions between the controller 404, the user 455 and/or the network manager 480. More specifically, the security module 428 authenticates communication from software based on security keys verifying the identity of the source of the communication. For example, user software may be associated with a security key enabling the software of the user 455 to interact with the controller 404. Further, the security module 428 can restrict receipt of information, requests for information, and/or access to information in some example embodiments.

FIG. 5 illustrates one embodiment of a computing device 518 that implements one or more of the various techniques described herein, and which is representative, in whole or in part, of the elements described herein pursuant to certain exemplary embodiments. Computing device 518 is one example of a computing device and is not intended to suggest any limitation as to scope of use or functionality of the computing device and/or its possible architectures. Neither should computing device 518 be interpreted as having any dependency or requirement relating to any one or combination of components illustrated in the example computing device 518.

Computing device 518 includes one or more processors or processing units 514, one or more memory/storage components 515, one or more input/output (I/O) devices 516, and a bus 517 that allows the various components and devices to communicate with one another. Bus 517 represents one or more of any of several types of bus structures, including a memory bus or memory controller, a peripheral bus, an accelerated graphics port, and a processor or local bus using any of a variety of bus architectures. Bus 517 includes wired and/or wireless buses.

Memory/storage component 515 represents one or more computer storage media. Memory/storage component 515 includes volatile media (such as random access memory (RAM)) and/or nonvolatile media (such as read only memory (ROM), flash memory, optical disks, magnetic disks, and so forth). Memory/storage component 515 includes fixed media (e.g., RAM, ROM, a fixed hard drive, etc.) as well as removable media (e.g., a Flash memory drive, a removable hard drive, an optical disk, and so forth).

One or more I/O devices 516 allow a customer, utility, or other user to enter commands and information to computing device 518, and also allow information to be presented to the customer, utility, or other user and/or other components or devices. Examples of input devices include, but are not limited to, a keyboard, a cursor control device (e.g., a mouse), a microphone, a touchscreen, and a scanner. Examples of output devices include, but are not limited to, a display device (e.g., a monitor or projector), speakers, outputs to a lighting network (e.g., DMX card), a printer, and a network card.

Various techniques are described herein in the general context of software or program modules. Generally, software includes routines, programs, objects, components, data structures, and so forth that perform particular tasks or implement particular abstract data types. An implementation of these modules and techniques are stored on or transmitted across some form of computer readable media. Computer readable media is any available non-transitory medium or non-transitory media that is accessible by a computing device. By way of example, and not limitation, computer readable media includes “computer storage media”.

“Computer storage media” and “computer readable medium” include volatile and non-volatile, removable and non-removable media implemented in any method or technology for storage of information such as computer readable instructions, data structures, program modules, or other data. Computer storage media include, but are not limited to, computer recordable media such as RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which is used to store the desired information and which is accessible by a computer.

The computer device 518 is connected to a network (not shown) (e.g., a local area network (LAN), a wide area network (WAN) such as the Internet, cloud, or any other similar type of network) via a network interface connection (not shown) according to some exemplary embodiments. Those skilled in the art will appreciate that many different types of computer systems exist (e.g., desktop computer, a laptop computer, a personal media device, a mobile device, such as a cell phone or personal digital assistant, or any other computing system capable of executing computer readable instructions), and the aforementioned input and output means take other forms, now known or later developed, in other exemplary embodiments. Generally speaking, the computer system 518 includes at least the minimal processing, input, and/or output means necessary to practice one or more embodiments.

Further, those skilled in the art will appreciate that one or more elements of the aforementioned computer device 518 is located at a remote location and connected to the other elements over a network in certain exemplary embodiments. Further, one or more embodiments is implemented on a distributed system having one or more nodes, where each portion of the implementation (e.g., PHM engine 106) is located on a different node within the distributed system. In one or more embodiments, the node corresponds to a computer system. Alternatively, the node corresponds to a processor with associated physical memory in some exemplary embodiments. The node alternatively corresponds to a processor with shared memory and/or resources in some exemplary embodiments.

FIG. 6 shows a temperature measuring device 640 and a corresponding output 641 used with example embodiments. In this case, the temperature measuring device 640 is an infrared sensor, and the output 641 is a thermal display that indicates the intensity of heat signatures based on the readings of the infrared sensor.

FIGS. 7 and 8 show graphs based on algorithms for monitoring the health of a circuit breaker in accordance with certain example embodiments. Specifically, FIGS. 7 and 8 show graphs of temperature versus current. Referring to FIGS. 1-8, the graph 770 of FIG. 7 shows a curve 773 that is a continuous plot of temperature 772 versus current 771 for a circuit breaker 450. The curve 773 is generated by an algorithm 433, calculated by the PHM engine 406, based on data points 774 (stored in the storage repository 430 as stored data 432) measured by the temperature measuring devices 440 and the power measuring devices 442 over time (as measured by the real-time clock 410). In this case, the curve 773 is best-fit plot based on the data points 774. The data points 774 can be for a particular circuit breaker 450 and/or for a number of circuit breakers that are determined to have one or more common characteristics.

In some cases, data points 775 may not reasonably fit within the curve 773 generated by the algorithm 433. In such a case, the PHM engine 406 can generate an alarm to notify a user 455 that there may be an issue with the accuracy of one or more of the temperature measurement devices 440 and/or the power measurement devices 442. Alternatively, if the temperature measurement devices 440 and the power measurement devices 442 are working properly, then the PHM engine 406 can alter the algorithm 433 to account for the new, accurate data points 775. As a result, the curve 773 can be altered.

The graph 890 of FIG. 8 shows two curves (curve 893 and curve 895) that are continuous plots of stimulus 891 versus probability 892. Curve 893 is generated by an algorithm 433, calculated by the PHM engine 406, based on data points 894 (stored in the storage repository 430 as stored data 432) measured by the temperature measuring devices 440 and the power measuring devices 442 over time (as measured by the real-time clock 410). In this case, the curve 893 is best-fit plot based on the data points 894. Similarly, curve 895 is generated by an algorithm 433, calculated by the PHM engine 406, based on data points 896 (stored in the storage repository 430 as stored data 432) measured by the temperature measuring devices 440 and the power measuring devices 442 over time (as measured by the real-time clock 410). In this case, the curve 895 is best-fit plot based on the data points 896.

At certain intervals (e.g., every week, every month, after every operation of the circuit breaker 450), the PHM engine 406 can evaluate the accuracy of one or more algorithms 433 and adjust an algorithm 433 as necessary. For example, a curve (e.g., curve 893) can be compared with a reference curve (e.g., curve 895) using a closeness-of-fit algorithm 433 (e.g., Chi-squared, Kolmogorov-Smirnov). If the curves fail to correlate, the PHM engine 406 can report to the user 455 that the circuit breaker 450 is failing. The extent of the deterioration of the circuit breaker 450 can be inferred by the disparity between the two curves.

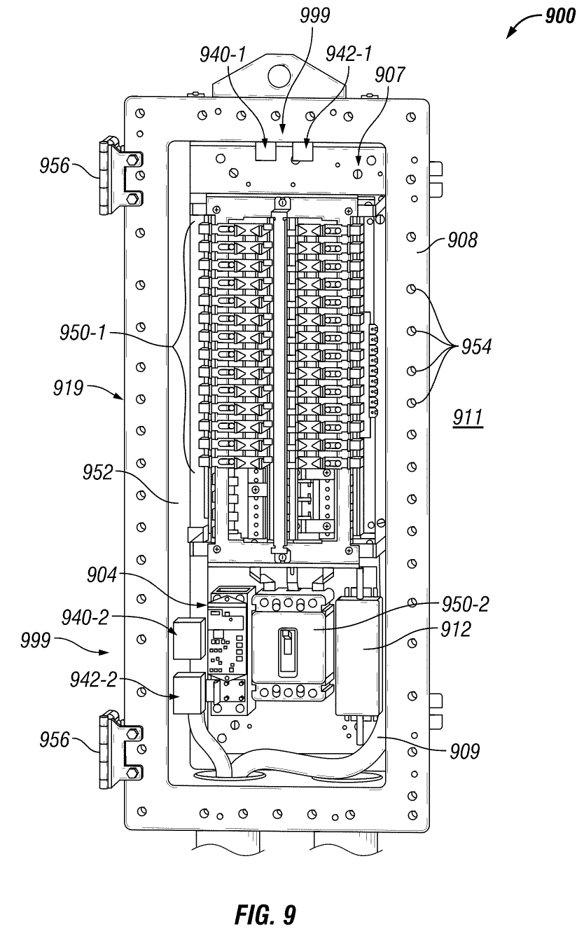

FIG. 9 shows a system 900 for monitoring circuit breakers in accordance with certain example embodiments. Specifically, referring to FIGS. 1-9, the system 900 of FIG. 9 includes an enclosure 919 that is substantially similar to the enclosure 119 of FIG. 1 above. For example, the enclosure 919 of FIG. 9 is in an open position (i.e., the enclosure cover (not shown) is separated from the enclosure body 952). The enclosure 919 is located in an ambient environment 911 (e.g., outdoors, a hazardous environment). The enclosure cover can be secured to the enclosure body 952 by a number of fastening devices (not shown) disposed within a number of apertures 954 around the perimeter of an enclosure engagement surface (not shown) (also called a flange) of the enclosure cover and around the perimeter of the enclosure engagement surface 908 (also called a flange 908) of the enclosure body 952.

When the enclosure cover and the enclosure body 952 are in the closed position relative to each other, the enclosure engagement surface 908 of the enclosure body 952 abuts against the enclosure engagement surface of the enclosure cover. When the enclosure 919 is an explosion-proof enclosure, as in this case, a flame path is formed between the enclosure engagement surface 908 of the enclosure body 952 and the enclosure engagement surface of the enclosure cover. The enclosure body forms a cavity 907 inside of which one or more components (e.g., circuit breakers 950, electrical cables 909, an example PHM system 999) are disposed. When the enclosure cover and the enclosure body 952 are in the closed position relative to each other, then the cavity 907 is substantially enclosed.

A fastening device may be one or more of a number of fastening devices, including but not limited to a bolt (which may be coupled with a nut), a screw (which may be coupled with a nut), and a clamp. In addition, one or more optional hinges 956 can be secured to one side of the enclosure cover and a corresponding side of the enclosure body 952 so that, when all of the fastening devices are removed, as shown in FIG. 9, the enclosure cover may swing outward (i.e., an open position) from the enclosure body 952 using the one or more hinges 956. In one or more example embodiments, there are no hinges, and the enclosure cover can be completely separated from the enclosure body 952 when all of the fastening devices are removed.

As stated above, a number of components are disposed within the cavity 907 of the enclosure 919. For example, in this case, a number of circuit breakers 950, electrical cables 909, and an example PHM system 999 are disposed within the cavity 907. Discrete components of the PHM system 999 that are disposed within the cavity 907 of FIG. 9 are the controller 904, the power module 912, two temperature measuring devices 940, and two power measuring devices 942. One temperature measuring device 940-1 and one power measuring device 942-1 are disposed along the top end of the cavity 907, proximate to the array of smaller circuit breakers 950-1, and the other temperature measuring device 940-2 and power measuring device 942-2 are disposed along the lower left side of the cavity 907, proximate to the relatively large circuit breaker 950-2. In this way, temperature measuring device 940-1 and one power measuring device 942-1 can measure one or more parameters associated with the array of circuit breakers 950-1, and temperature measuring device 940-2 and power measuring device 942-2 can measure one or more parameters associated with circuit breaker 950-2.

Example embodiments can generate estimates of the remaining useful life of a circuit breaker or components thereof based on actual, real-time data, both from a particular circuit breaker and from a pool of circuit breakers, evaluated over time. Example embodiments can predict the failure of a circuit breaker (or components thereof) to improve the safety of industrial environments in which the circuit breaker is disposed. In some cases, example embodiments can project when an impending fault may occur due to measured information (e.g., temperature rise over time, use characteristics). Example embodiments can also help ensure efficient allocation of maintenance resources within a facility. Example embodiments can further provide a user with options to prolong the useful life of a circuit breaker or components thereof.

Although embodiments described herein are made with reference to example embodiments, it should be appreciated by those skilled in the art that various modifications are well within the scope and spirit of this disclosure. Those skilled in the art will appreciate that the example embodiments described herein are not limited to any specifically discussed application and that the embodiments described herein are illustrative and not restrictive. From the description of the example embodiments, equivalents of the elements shown therein will suggest themselves to those skilled in the art, and ways of constructing other embodiments using the present disclosure will suggest themselves to practitioners of the art. Therefore, the scope of the example embodiments is not limited herein.

What is claimed is:

1. A system comprising:
at least one circuit breaker;
a prognostic and health monitoring (PHM) system comprising:
at least one measuring device that measures at least one parameter associated with the at least one circuit breaker; and
a controller that receives measurements made by the at least one measuring device and analyzes the measurements to evaluate a performance of the at least one circuit breaker,
wherein the measurements are made while the at least one circuit breaker is in service.

2. The system of claim 1, wherein the at least one parameter comprises at least one selected from a group consisting of a current and a temperature.

3. The system of claim 2, wherein, when the at least one parameter is the temperature, the at least one measuring device that measures the temperature is at least one selected from a group consisting of a thermocouple, a thermistor, and an infrared sensor.

4. The system of claim 3, wherein, when the at least one parameter is the temperature, the at least one measuring device is directed at the at least one circuit breaker to measure the temperature.

5. The system of claim 2, wherein the current flows through the at least one circuit breaker.

6. The system of claim 1, wherein the controller uses at least one algorithm with the measurements to determine whether the at least one circuit breaker is failing.

7. The system of claim 6, wherein the controller operates using a hardware processor.

8. The system of claim 1, wherein the measurements are stored and compared with more recent measurements.

9. The system of claim 8, wherein the controller adjusts the at least one algorithm over time based on the measurements relative to data collected during an inspection of the at least one circuit breaker.

10. The system of claim 1, wherein the controller sends a communication to a user, wherein the communication is associated with evaluating the performance of the at least one circuit breaker.

11. The system of claim 10, wherein the performance of the at least one circuit breaker comprises at least one device receiving power through the at least one circuit breaker.

12. The system of claim 1, wherein the at least one circuit breaker and at least a portion of the PHM system are disposed within a cavity of an enclosure.

13. The system of claim 12, wherein the enclosure is an explosion-proof enclosure.

14. The system of claim 1, further comprising:
a network manager communicably coupled to the controller, wherein the network manager sends instructions to the controller.

15. The system of claim 14, wherein the PHM system further comprises a transceiver to facilitate communications between the controller and the network manager.

16. A prognostic and health monitoring (PHM) system comprising:
at least one measuring device that is configured to measure at least one parameter associated with at least one circuit breaker; and
a controller configured to receive measurements made by the at least one measuring device and analyze the measurements to evaluate a performance of the at least one circuit breaker,
wherein the measurements are made while the at least one circuit breaker is in service.

17. The PHM system of claim 16, wherein the at least one measuring device comprises a temperature measuring device.

18. The PHM system of claim 16, wherein the at least one measuring device comprises a power measuring device.

19. The PHM system of claim 16, further comprising:
a storage repository for storing the measurements and at least one algorithm for analyzing the measurements; and
a hardware processor for performing calculations using the at least one algorithm.

20. A controller for evaluating a performance of at least one circuit breaker, the controller comprising:
a memory comprising a plurality of instructions;
a hardware processor that executes the plurality of instructions; and
a control engine that follows the plurality of instructions by:
receiving a measurement from at least one measuring device, wherein the measurement is associated with at least one circuit breaker;
analyzing the measurement in the context of at least one algorithm; and
determining, based on analyzing the measurement, a performance of the at least one circuit breaker,
wherein the measurement is made while the at least one circuit breaker is in service.
